(19) United States
(12) Patent Application Publication
(10) Pub. No.: US 2009/0307561 A1
(43) Pub. Date: Dec. 10, 2009

(54) Decoding device, decoding method, and recording and reproducing device

(75) Inventor: Toshikazu KANAOKA, Kawasaki (JP)

Correspondence Address: STAAS & HALSEY LLP, SUITE 700, 1201 NEW YORK AVENUE, N.W., WASHINGTON, DC, 20005, US

(73) Assignee: Fujitsu Limited, Kawasaki (JP)

(21) Appl. No.: 12/385,070

(22) Filed: Mar. 30, 2009

(30) Foreign Application Priority Data
Jun. 5, 2008 (JP) 2008-148473

(51) Int. Cl. H03M 13/27; G06F 11/10

(52) U.S. Cl. 714/752; 714/E11.032; 714/784

(57) ABSTRACT

A decoding device includes a decoding unit that decodes an information data string including an error-correction parity for each interleaved data string obtained by interleaving the information data string for each symbol to generate a decoded data string; an error-correcting decoding unit that interleaves the decoded data string to perform error-correcting decoding, de-interleaves the interleaved decoded data strings after error-correcting decoding when all errors in the decoded data strings are corrected, and generates a decoded data string after error correction when errors are remained; and an event error-correcting unit that corrects data in the decoded data string for the merge section when an error-corrected portion in the decoded data string obtained by comparing the decoded data string and the decoded data string after error correction is in an event information string indicative of a merge section in the decoded data string.

### CROSS-REFERENCE TO RELATED APPLICATION

This application is based upon and claims the benefit of priority of the prior Japanese Patent Application No. 2008-148473, filed on Jun. 5, 2008, the entire contents of which are incorporated herein by reference.

### FIELD

The embodiments discussed herein are directed to a decoding device, decoding method, and recording and reproducing device.

### BACKGROUND

In a technological field using recording and reproducing devices, communication devices, and other devices, for the purpose of improving reliability of data reproduced in the course of recording and reproduction and data transmitted over a transmission path, error correcting techniques have been widely used in which an error occurring in data is corrected with Error Correcting Code (ECC).

For example, in a magnetic disk device, Reed-Solomon codes are used for correcting an error in an algebraic manner through calculation based on a Galois field. With a q-bit unit represented by a Galois field GF (2^{q}) (hereinafter, referred to as a symbol) as a data correction unit, error correction of information data is performed (where q is an integer equal to or greater than 1).

Also, for calculation based on the Galois field GF (2^{q}), the maximum code length of Reed-Solomon codes is restricted by the value of q. Furthermore, as the value of q is larger, the amount of calculation exponentially increases. Therefore, an interleave technique is adopted for error correction by using the Reed-Solomon codes (for example, see H. Sawaguchi, et al., IEEE Transaction on Magnetics, vol. 37, No. 2, March 2001).

In the interleave technique, information data is interleaved into a plurality of code strings for each symbol, and each code string obtained through division is encoded with the Reed-Solomon code, thereby reducing the code length (reducing the amount of calculation).

However, when the interleave technique explained above is used, the following problems arise. That is, since code strings obtained through division by the interleave technique are independent from each other without correlation, when the number of errors exceeds a maximum correctable number in a code string and therefore the errors cannot be corrected, a sector including that code string becomes an incorrect sector even other code strings in that sector are correctable, resulting in a decrease in correction capability.

### SUMMARY

According to an aspect of the invention, a decoding device includes a decoding unit that decodes an information data string including an error-correction parity for each interleaved data string obtained by interleaving the information data string for each symbol to generate a decoded data string; an error-correcting decoding unit that interleaves the decoded data string input from the decoding unit for each symbol to perform error-correcting decoding, de-interleaves the interleaved decoded data strings after error-correcting decoding for output when all errors in the interleaved decoded data strings are corrected, and generates a decoded data string after error correction obtained by de-interleaving the interleaved decoded data strings after error-correcting decoding when errors are remained in any of the interleaved decoded data strings; and an event error-correcting unit that receives the decoded data string from the decoding unit and the decoded data string after error correction from the error-correcting decoding unit, and when an error-corrected portion in the decoded data string obtained by comparing the decoded data string and the decoded data string after error correction is in an event information string indicative of a merge section in the decoded data string, and corrects data in the decoded data string for the merge section.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a drawing for explaining a general outline of a magnetic disk device according to a first embodiment;

FIG. 2 is a drawing for explaining the general outline of the magnetic disk device according to the first embodiment;

FIG. 3 is a block diagram of the configuration of the magnetic disk device according to the first embodiment;

FIG. 4 is a block diagram of the configuration of an error-correcting encoder according to the first embodiment;

FIG. 5 is a block diagram of the configuration of a Viterbi decoder according to the first embodiment;

FIG. 6 is a drawing for use in explaining the operation of the Viterbi decoder according to the first embodiment;

FIG. 7 is a drawing for use in explaining the operation of the Viterbi decoder according to the first embodiment;

FIG. 8 is a drawing for use in explaining the operation of the Viterbi decoder according to the first embodiment;

FIG. 9 is a block diagram of the configuration of an error-correcting decoder and an event error corrector according to the first embodiment;

FIG. 10 is a data flow according to the first embodiment;

FIG. 11 is a flowchart of an operation flow of the magnetic disk device according to the first embodiment;

FIG. 12 is a block diagram of the configuration of a magnetic disk device according to a second embodiment;

FIG. 13 is a block diagram of the configuration of a parity-likelihood error corrector, error-correcting decoder, and event-likelihood error corrector according to the second embodiment;

FIG. 14 is a flowchart of an operation flow of the magnetic disk device according to the second embodiment; and

FIG. 15 is a drawing for explaining a data interleaving method according to a third embodiment.

### DESCRIPTION OF EMBODIMENTS

With reference to the attached drawings, embodiments of the decoding device, decoding method, and recording and reproducing device according to the present invention are explained in detail below. In the following, a magnetic disk device is taken as an example for explanation.

### First Embodiment

[General Outline of the Magnetic Disk Device (First Embodiment)]

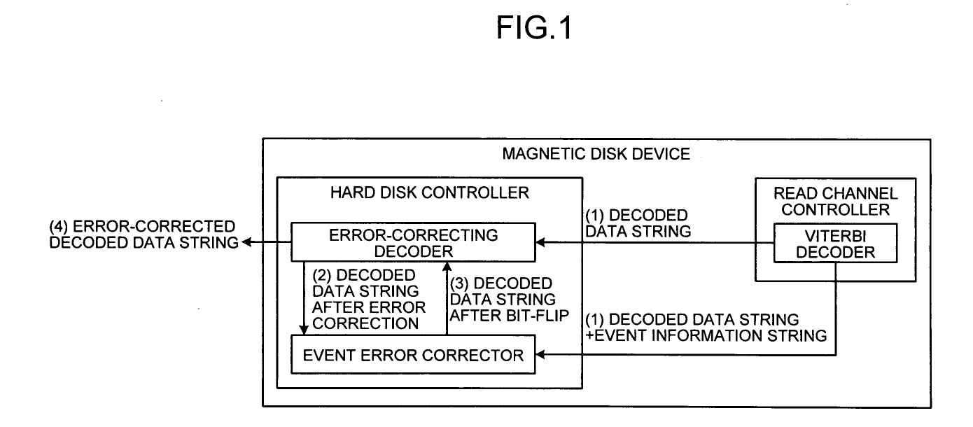

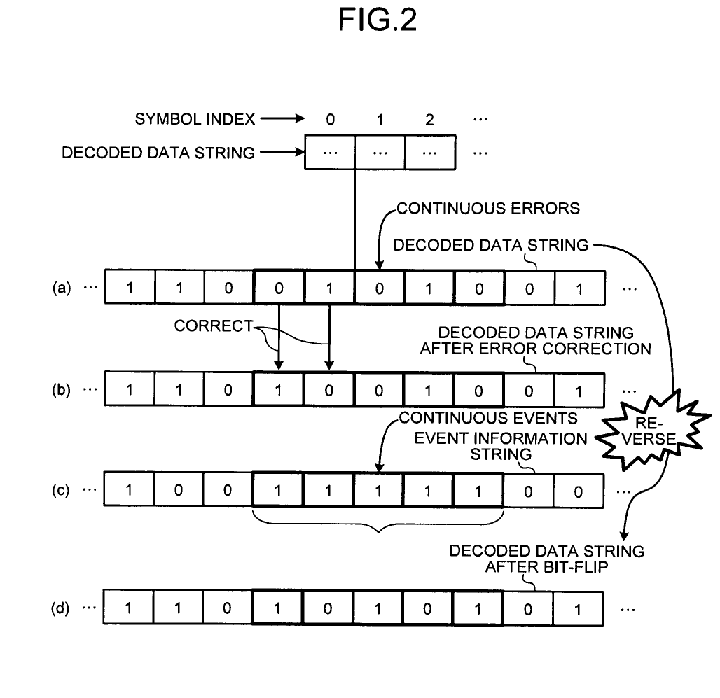

FIGS. 1 and 2 are drawings for explaining a general outline of a magnetic disk device according to a first embodiment.

The magnetic disk device according to the first embodiment can be summarized as performing error correction of a decoded data string obtained by decoding a reproduction signal obtained by reproducing data on a magnetic disk.

For example, as depicted in FIG. 1, the magnetic disk device according to the first embodiment includes a read channel controller and a hard disk controller.

The read channel controller includes a Viterbi decoder, while the hard disk controller includes an error-correcting decoder and an event error corrector.

The Viterbi decoder performs Viterbi decoding on a reproduction signal obtained by reproducing from a recording medium an error-corrected data string obtained by adding to an information data string an error-correcting parity for each interleaved data string obtained by interleaving an information data string for each symbol, thereby generating a decoded data string and an event information string indicative of a merge section in the decoded data.

As will be explained in detail further below, when a reproduced data string obtained by equalizing the waveform of a reproduction signal makes a state transition with time “from 0 to 0” or “from 0 to 1” and “from 1 to 0” or “from 1 to 1”, the event information string indicates information about a merge section (continuous events) between merges where the reproduction data string is determined to make a state transition from “0” or “1” at a predetermined time.

The Viterbi decoder then outputs the decoded data string to the error-correcting decoder, and also outputs the decoded data string and the event information to the event error corrector (see (1) in FIG. 1).

The error-correcting decoder interleaves the decoded data string input from the Viterbi decoder for each symbol for error-correcting decoding. When errors are remained for each decoded data string, the error-correcting decoder outputs to the event error corrector a decoded data string after error correction obtained by de-interleaving the decoded data strings after error-correcting decoding (see (2) in FIG. 1).

When an error-corrected portion in the decoded data string obtained by comparing the decoded data string input from the Viterbi decoder and the error-corrected decoded data string input from the error-correcting decoder is in the event information string input from the Viterbi decoder, the event error corrector bit-flips the data in the decoded data string for the merge section (continuous events).

Specifically, with reference to FIG. 2, the event error corrector compares a decoded data string (for example, see (a) in FIG. 2) and an error-corrected decoded data string (for example, see (b) in FIG. 2) to obtain an error-corrected portion in the decoded data string.

Then, when the obtained error-corrected portion in the decoded data string is in the event information string (for example, see (c) in FIG. 2), the event-error corrector bit-flips the data in the decoded data string for the merge section (continuous events) (for example, see (d) in FIG. 2).

Referring back to FIG. 1, the event-error corrector returns the decoded data string after bit-flip to the error-correcting decoder (see (3) in FIG. 1).

The error-correcting decoder interleaves the decoded data string after bit-flip returned from the event error corrector for each symbol for error-correcting decoding. When every error in the decoded data strings is corrected, the error-correcting decoder de-interleaves the decoded data strings after error-correcting decoding, and outputs the result to the outside (see (4) in FIG. 1).

As explained above, in the magnetic disk device according to the first embodiment, the event information string is used to provide a correlation between adjacent symbols. With this, continuous errors in the decoded data string across symbols can be corrected by bit-flip without causing an incorrect sector even with the use of the interleave technique (for example, see FIG. 2), thereby achieving a high correction capability.

[Configuration of the Magnetic Disk Device (First Embodiment)]

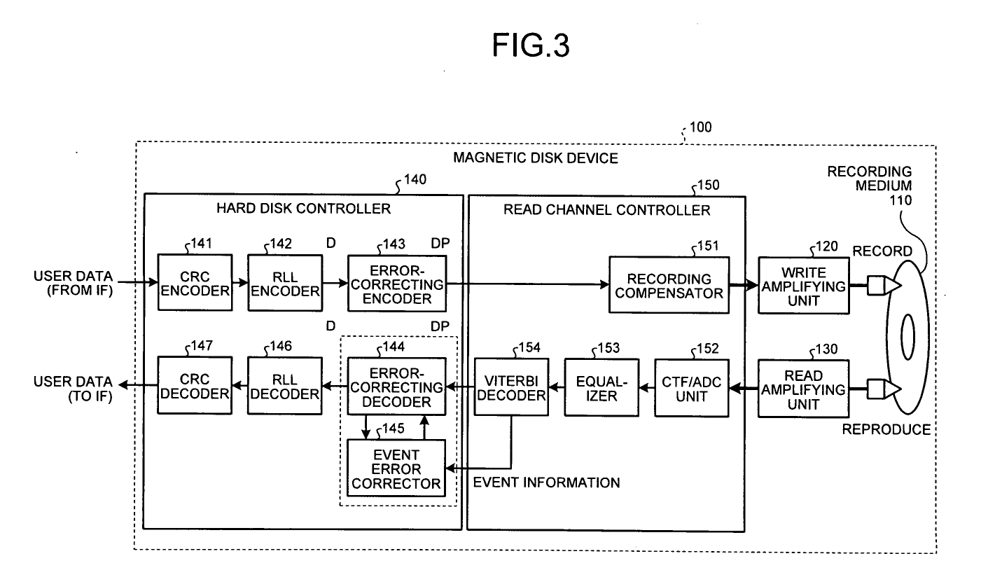

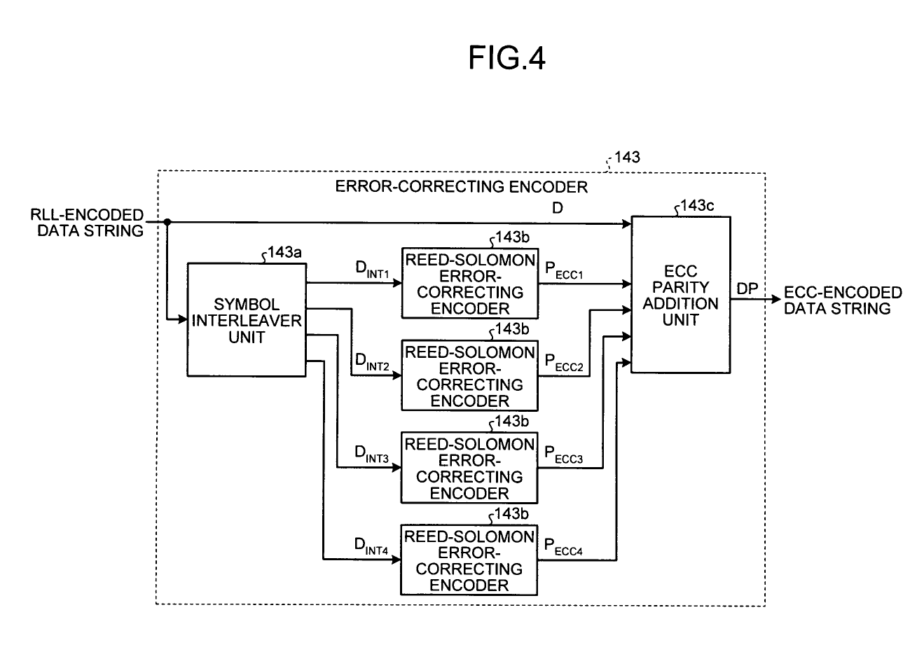

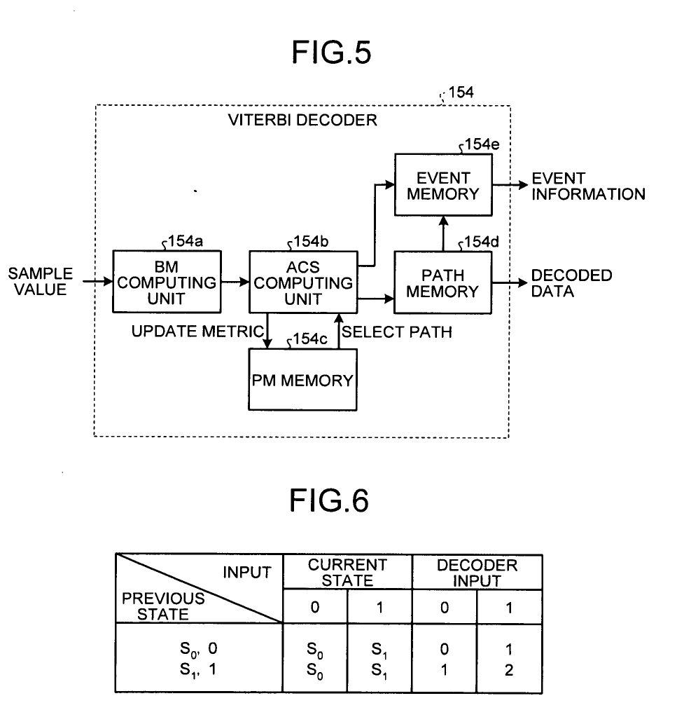

FIG. 3 is a block diagram of the configuration of the magnetic disk device according to the first embodiment. FIG. 4 is a block diagram of the configuration of the error-correcting encoder according to the first embodiment. FIG. 5 is a block diagram of the configuration of the Viterbi decoder according to the first embodiment.

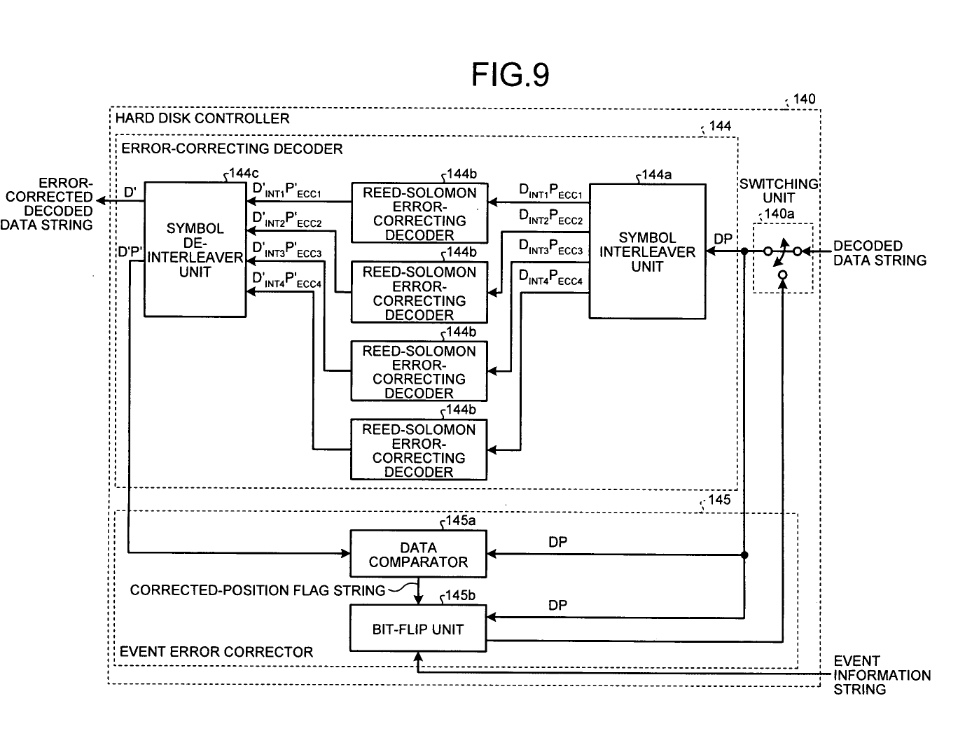

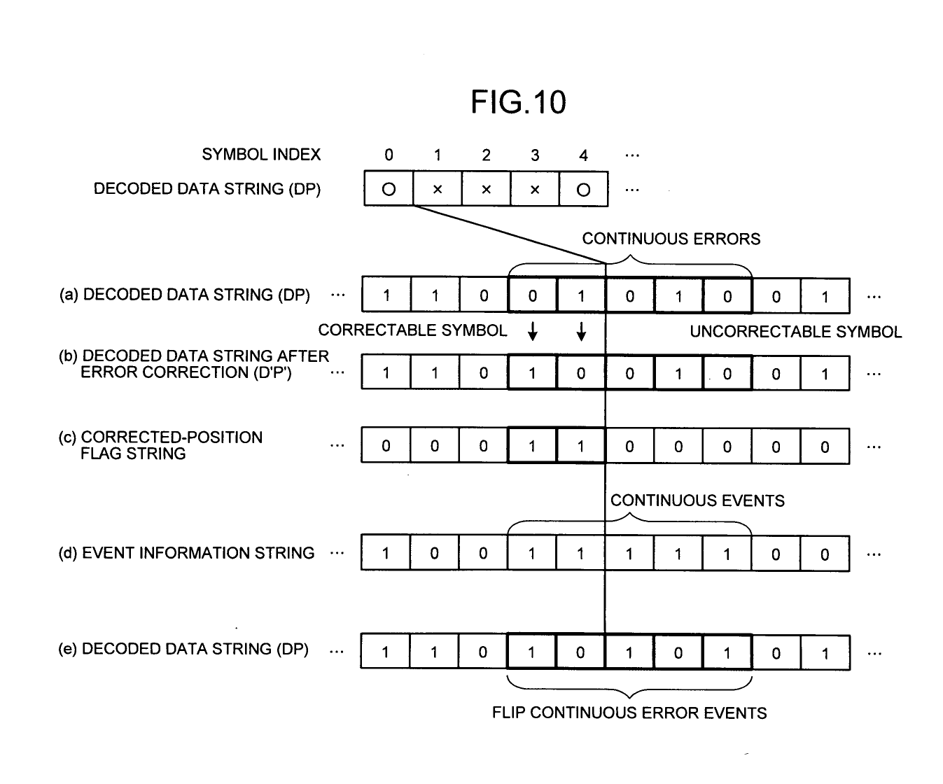

FIGS. 6 to 8 are drawings for use in explaining the operation of the Viterbi decoder according to the first embodiment. FIG. 9 is a block diagram of the configuration of the error-correcting decoder and the event error corrector according to the first embodiment. FIG. 10 is a data flow according to the first embodiment.

As depicted in FIG. 3, a magnetic disk device 100 according to the first embodiment includes a recording medium 110, a write amplifying unit 120, a read amplifying unit 130, a hard disk controller 140, and a read channel controller 150.

The recording medium 110 is a medium on which data is recorded by using a magnetic head. The write amplifying unit 120 is a device that controls a recording voltage when data is recorded on the recording medium 110 by using the magnetic head. The read amplifying unit 130 is a device that controls a reproduction voltage when data is reproduced from the recording medium 110 by using the magnetic head.

The hard disk controller 140 is a device mainly for error-correcting and encoding user data configured of binary values of “0” or “1” input via an interface and for error-correcting and decoding a decoded data string input from the read channel controller 150.

The hard disk controller 140 includes, as depicted in FIG. 3, a Cyclic Redundancy Check (CRC) encoder 141, a Run Length Limited (RLL) encoder 142, an error-correcting encoder 143, an error-correcting decoder 144, an event error corrector 145, an RLL decoder 146, and a CRC decoder 147.

The CRC encoder 141 is a device that uses CRC codes to encode user data configured of binary values of “0” or “1” input via the interface for output to the RLL encoder 142.

The RLL encoder 142 uses RLL codes to encode the encoded data string input from the CRC encoder 141 for output to the error-correcting encoder 143.

The error-correcting encoder 143 is a device that adds an ECC parity to the encoded data string input from the RLL encoder 142 for output to the read channel controller 150, and includes, as depicted in FIG. 4, a symbol interleaver unit 143a, a plurality of Reed-Solomon error-correcting encoders 143b, and an ECC parity addition unit 143c.

The symbol interleaver unit 143a interleaves the encoded data string input from the RLL encoder 142 for each symbol (for example, q-bit symbol, where q is an integer equal to or greater than 1) to interleave the data strings obtained through division for output to the Reed-Solomon error-correcting encoders 143b.

For example, when symbol indexes of the encoded data string input from the RLL encoder 142 are “0, 1, 2, 9, . . . ”, symbol indexes of a data string D_{INT1} obtained through division and input to the Reed-Solomon error-correcting encoder 143b disposed at the top is “0, 4, 8, . . . ”.

Also, for example, symbol indexes of data D_{INT2} input to the Reed-Solomon error-correcting encoder 143b disposed at the next stage are “1, 5, 9, . . . ”.

Furthermore, for example, symbol indexes of data D_{INT3} input to the Reed-Solomon error-correcting encoder 143b disposed at the further next stage are “2, 6, 10, . . . , ”.

Still further, for example, symbol indexes of data DINT₄ input to the Reed-Solomon error-correcting encoder 143b disposed at the lowest stage are “3, 7, 11, . . . ”.

The Reed-Solomon error-correcting encoders 143b each generate an ECC parity of 2t symbols when the Galois field GF(2^{q}) is taken as a base and, for example, when a q-bit symbol is provided and a maximum number of symbol error corrections is taken as t (where t is an integer equal to or greater than 1).

For example, as depicted in FIG. 4, the Reed-Solomon error-correcting encoders 143b uses a Reed-Solomon code to generate ECC parity data strings (P_{ECC1} to P_{ECC4}) for data strings (D_{INT1} to D_{INT4}) obtained through division and input from the symbol interleaver unit 143a, and then outputs these ECC parity data strings to the ECC parity addition unit 143c.

The ECC parity addition unit 143c adds the ECC parity data strings (P_{ECC1} to P_{ECC4}) input from the Reed-Solomon error-correcting encoders 143b into the encoded data string input from the RLL encoder 142 to generate an ECC-encoded data string (DP) for output to the read channel controller 150.

The read channel controller 150 is a device that mainly controls recording and reproducing operations into and from the recording medium 110 and includes, as depicted in FIG. 3, a recording compensator 151, a Continuous Timing Filter (CTF)/Analog Digital Converter (ADC) unit 152, an equalizer 153, and a Viterbi decoder 154.

The recording compensator 151 is a device that records and compensates the ECC-encoded data string (DP) input from the hard disk controller 140. After recording and compensating, the ECC-encoded data string (DP) is recorded on the recording medium 110 via the write amplifying unit 120 and the magnetic head.

The CTF/ADC unit 152 is a device that filters the reproduction signal input via a reproducing head and the read amplifying unit 130 with an analog filter (CTF), and also converts the reproduction signal with an ADC to generate a reproduced data string. The CTF/ADC unit 152 inputs the generated reproduced data string to the equalizer 153.

The equalizer 153 is a device that equalizes the waveform of the reproduced data string, and outputs to the Viterbi decoder 154 the reproduced data string subjected to waveform equalization.

The Viterbi decoder is a device that decodes the reproduced data string input from the equalizer 153 to generate a decoded data string detected as binary data formed of “0” and “1” and an event information string indicative of a merge section (event) in the decoded data string, and outputs these strings to the hard disk controller 140.

The Viterbi decoder 154 includes, as depicted in FIG. 5, a Branch Metric (BM) computing unit 154a, an Add Compare Select (ACS) computing unit 154b, a Path Metric (PM) memory 154c, a path memory 154d, and an event memory 154e.

The BM computing unit 154a is a computing unit that performs a BM computation on the reproduced data string input from the equalizer 153, and inputs the calculated BM value to the ACS computing unit 154b.

Specifically, as depicted in FIG. 6, the BM computing unit 154a sets a decoder input when the reproduced data string makes a state transition with time between binary data “0” and “1”.

For example, four state transitions of the reproduced data string can be assumed: “0→0”, “0→1”, “1→0”, and “1→1”. As depicted in FIG. 6, the decoder input is set as “0” for a transition “S₀=0=S₀=0”, the decoder input is set as “1” for a transition “S₀=0→S₁=1”, the decoder input is set as “1” for a transition “S₁=1→S₀=0”, and the decoder input is set as “2” for a transition “S₁=1→S₁=1”.

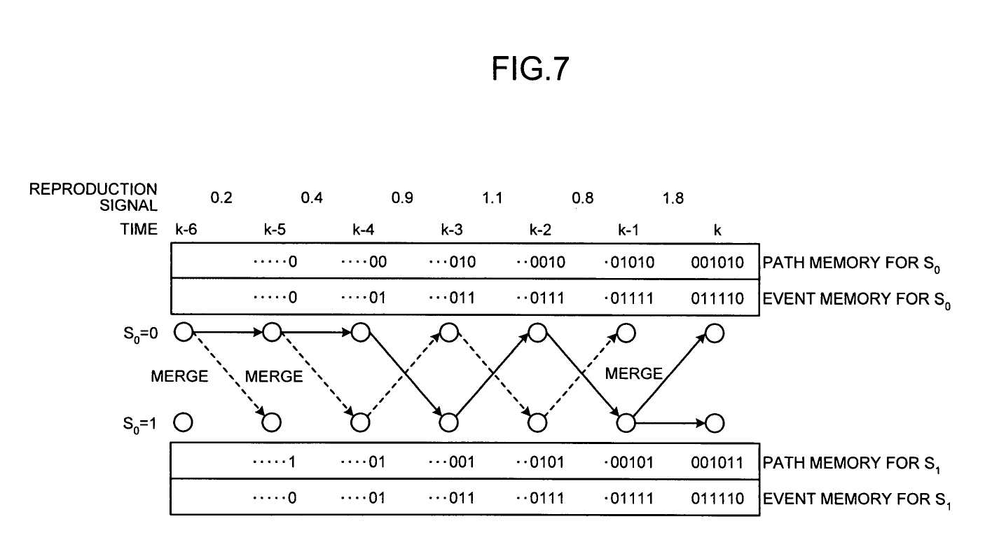

As depicted in FIG. 7, the BM computing unit 154a calculates each BM value due to a state transition by using decoder inputs set as inputs from the previous state of “S₀=0” and “S₁=1” for the current states “S₀=0” and “S₁=1” at a predetermined time (for example, k-5) (see FIG.6) and an input of the reproduction signal at the current time (for example, 0.2), and then outputs the BM value to the ACS computing unit 154b.

The ACS computing unit 154b is a computing unit that defines a merge section of the reproduced data string input from the equalizer 153 by using each BM value input from the BM computing unit 154a.

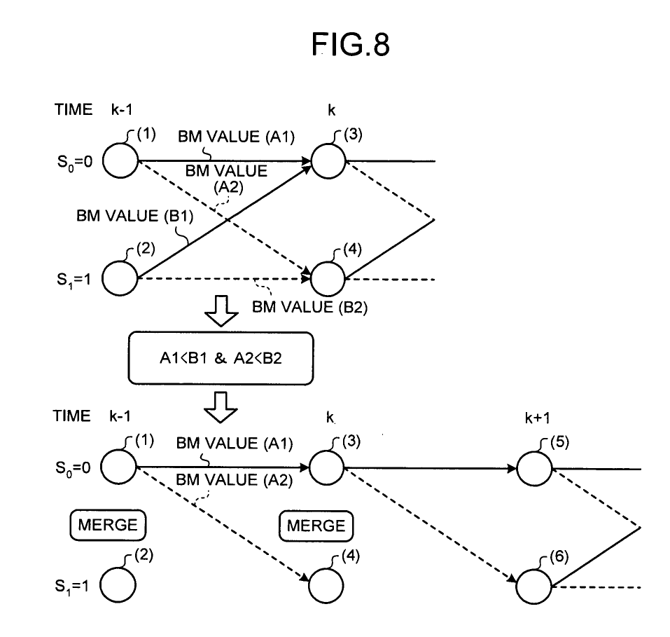

Specifically, as depicted in FIG. 8, it is assumed that the ACS computing unit 154b accepts from the BM computing unit 154a inputs of BM values A1 and A2 on paths (indicated by arrows) connecting “S₀=0” at a time “k-1” (see (1) in an upper portion of FIG. 8), and “S₀=0” at a time “k” (see (3) in the upper portion of FIG. 8) and “S₁=1” at the time “k” (see (4) in the upper portion of FIG. 8) together.

Similarly, as depicted in FIG. 8, it is assumed that the ACS computing unit 154b accepts from the BM computing unit 154a inputs of BM values B1 and B2 on paths (indicated by arrows) connecting “S₁=1” at the time “k-1” (see (2) in the upper portion of FIG. 8), and “S₀=0” at the time “k” (see (3) in the upper portion of FIG. 8) and “S₁=1” at the time “k” (see (4) in the upper portion of FIG. 8) together.

In such a case, in “S₀=0” at the time “k” (see (3) in FIG. 8), the ACS computing unit 154b compares A1 and B1, which are BM values on the connected paths, to select, for example, a path corresponding to A1, which is a smaller BM value.

Similarly, in “S₁=1” at the time “k” (see (4) in FIG. 8), the ACS computing unit 154b compares A2 and B2, which are BM values on the connected paths, to select, for example, a path corresponding to A2, which is a smaller BM value.

As a result, when paths connecting “S₀=0” at the time “k-1” and “S₀=0” and “S₁=1” at the time “k” are survived, the ACS computing unit 154b defines the state of the reproduced data string at the predetermined time “k-1” as “S₀=0” and “merge” (see FIG. 8).

On the other hand, as a result of comparison between the BM values, when a path connecting “S₀=0” at the time “k-1” and “S₁=1” at the time “k” and a path connecting “S₁=1” at the time “k-1” and “S₀=0” at the time “k” are selected, the ACS computing unit 154b defines the state of the reproduced data string at the predetermined time “k-1” as neither “S₀=0” nor “S₁=1” and “non-merge”.

Then, the ACS computing unit 154b performs a path selection and a determination of defining as “merge” for each predetermined time of the reproduced data string in a manner similar to that explained above. When determining as “merge”, the ACS computing unit 154b writes in the event memory 154e “0” or “1” different from the immediately-previous value written in the event memory.

On the other hand, when determining as “non-merge”, the ACS computing unit 154b writes in the event memory 154e “0” or “1” same as the immediately-previous value. written in the event memory (see FIGS. 5 and 7).

Also, every time the ACS computing unit 154b performs a path selection and a determination of defining as “merge”, the ACS computing unit 154b overwrites and updates the PM memory 154c with a BM value corresponding to the selected path as a metric value to be added to the BM value on the path from each previous state (“S₀=0” or “S₁=1”) at a path selection and a determination of defining as “merge” at the next time.

Furthermore, every time the ACS computing unit 154b performs a path selection and a determination of defining as “merge”, the ACS computing unit 154b writes in the path memory 154d state transition data (binary data) of the reproduced data string as decoded data.

The path memory 154d outputs the decoded data string written by the ACS computing unit 154b to the hard disk controller 140.

For example, as depicted in FIG. 7, the path memory 154d outputs a data string written in the path memory of S₁ continuing a state transition even after merge as a decoded data string to the hard disk controller 140.

The event memory 154e outputs the data string written by the ACS computing unit 154b as an event information data string to the hard disk controller 140.

In the event error corrector 145 of the hard disk controller 140 explained below, with reference to the event information data string input from the Viterbi decoder 154, from a point where data is switched (“1”⇄“0”), a section is specified as a merge section (continuous events) in the decoded data string input also from the Viterbi decoder 154.

Specifically, for example, as depicted in FIG. 7, the event error corrector 145 specifies a section from a time “k-5” immediately before the time when data written in the event memory 154e is switched from “0” to “1” to a time “k-1” immediately before the time when the data is switched from “1” to “0” as a merge section (continuous events) of the decoded data string input from the path memory 154d.

Now referring back to the explanation of the hard disk controller 140, in particular, the error-correcting decoder 144 and the event error corrector 145 are explained by using FIGS. 9 and 10.

The error-correcting decoder 144 is a decoder that performs error-correcting decoding on the decoded data string input from the Viterbi decoder 154 of the read channel controller 150. As depicted in FIG. 9, the error-correcting decoder 144 includes a symbol interleaver unit 144a, a plurality of Reed-Solomon error-correcting decoders 144b, and a symbol de-interleaver unit 144c.

As with the symbol interleaver unit 143a, the symbol interleaver unit 144a interleaves a decoded data string (DP), and distributes ECC parity data strings (P_{ECC1} to P_{ECC4}) to decoded data strings obtained through division (D_{INT1} to D_{INT4}) for output to the Reed-Solomon error-correcting decoders 144b.

The Reed-Solomon error-correcting decoders 144b correspond to the Reed-Solomon error-correcting encoders 143b. For example, each Reed-Solomon error-correcting decoder 144b takes the Galois field GF(2^{q}) as a base, and performs error correction when a q-bit symbol is provided and a maximum number of symbol error corrections is taken as t for the decoded data string input from the symbol interleaver unit 144a.

Specifically, when the number of symbol errors of the decoded data string input from the symbol interleaver unit 144a is equal to or smaller than the maximum number of symbol error corrections t, the Reed-Solomon error-correcting decoder 144b performs symbol error correction on the input decoded data string, and outputs the error-corrected decoded data string, which is a correctable symbol, to the symbol de-interleaver unit 144c.

On the other hand, when the number of symbol errors of the decoded data string input from the symbol interleaver unit 144a is greater than the maximum number of symbol error corrections t, the Reed-Solomon error-correcting decoder 144b outputs the input decoded data string as it is to the symbol de-interleaver unit 144c as an error-corrected decoded data string, which is incorrect symbol.

The symbol de-interleaver unit 144c checks to see whether all symbol errors in the error-corrected decoded data strings (D′_{INT1}P′_{ECC1} to D′_{INT4}P′_{ECC4}) input from the Reed-Solomon error-correcting decoders 144b have been corrected.

As a result of the check, when determining that all symbol errors in the error-corrected decoded data strings (D′_{INT1}P′_{ECC1} to D′_{INT4}P′_{ECC4}) input from the Reed-Solomon error-correcting decoders 144b have been corrected, the symbol de-interleaver unit 144c outputs to the outside an error-corrected decoded data string (D′) obtained by deleting the ECC parity data string from the decoded data string after error correction for de-interleave.

On the other hand, when a symbol error is remained in any of the error-corrected decoded data strings (D′_{INT1}P′_{ECC1} to D′_{INT4}P′_{ECC4}) input from the Reed-Solomon error-correcting decoders 144b, the symbol de-interleaver unit 144c outputs a decoded data string (D′P′) obtained by de-interleaving the error-corrected decoded data strings to the event error corrector 145 (for example, see (a) in FIG. 10).

The event error corrector 145 is a corrector that performs error correction on the decoded data string after error correction (D′P′) input from the symbol de-interleaver unit 144c, and includes, as depicted in FIG. 9, a data comparator 145a and a bit-flip unit 145b.

The data comparator 145a compares the decoded data string after error correction (D′P′) input from the symbol de-interleaver unit 144c (for example, see (b) in FIG. 10) and the decoded data string (DP) input from the Viterbi decoder 154 via a switching unit 140a to generate a corrected-position flag string indicative of an error-corrected portion in the decoded data string (DP) (for example, see (c) in FIG. 10), and then outputs the generated string to the bit-flip unit 145b together with the decoded data string after error correction (D′P′).

Based on the decoded data string (DP) and the event information string (see (d) in FIG. 10) input from the Viterbi decoder 154 via the switching unit 140a and the corrected-position flag input from the data comparator 145a, the bit-flip unit 145b checks to see whether the corrected portion in the decoded data string is in the event information string indicative of a merge section in the decoded data string (in continuous events), and performs error correction by bit-flipping the data in the decoded data string (DP).

Specifically, when it is confirmed based on the corrected-position flag input from the data comparator 145a that the corrected portion in the decoded data string also input from the data comparator 145a is in the event information string (continuous events) indicative of a merge section in the decoded data string, the bit-flip unit 145b bit-flips the data in the decoded data string for the merge section (continuous events) (change as “0→1” or “1→0” for correction: for example, see (e) in FIG. 10).

The bit-flip unit 145b then outputs the decoded data string after correction again to the symbol interleaver unit 144a via the switching unit 140a.

On the other hand, when it is not confirmed based on the corrected-position flag input from the data comparator 145a that the corrected portion in the decoded data string is in the event information string (in the continuous events), the bit-flip unit 145b outputs the decoded data string after error correction (D′P′) as it is to the symbol interleaver unit 144a.

The symbol interleaver unit 144a interleaves the decoded data string after correction (or after error correction) input from the bit-flip unit 145b via the switching unit 140a and then again outputs to the Reed-Solomon error-correcting decoders 144b.

As explained above, each Reed-Solomon error-correcting decoder 144b performs error correction on the decoded data string input from the symbol interleaver unit 144a, and then outputs the decoded data string after error correction to the symbol de-interleaver unit 144c.

As explained above, the symbol de-interleaver unit 144c checks the correction state of a symbol error in the error-corrected decoded data string input from each Reed-Solomon error-correcting decoder 144b for output to the outside as a corrected decoded data string (D′), or outputs the error-corrected decoded data string (D′P′) to the event error corrector 145.

In this manner, error correction is iteratively performed between the error-correcting decoder 144 and the event error corrector 145 until an error-corrected decoded data string with all symbol errors corrected is output from the error-correcting decoder 144 of the hard disk controller 140 to the outside.

Here, the error correction iteratively performed between the error-correcting decoder 144 and the event error corrector 145 is not meant to be restricted to an error correction iterated until an error-corrected decoded data string with all symbol errors corrected is output to the outside. An error-corrected decoded data string may be output to the outside after an error correction is iterated a predetermined number of times, irrespectively of the correction result.

[Process of the Magnetic Disk Device (First Embodiment)]

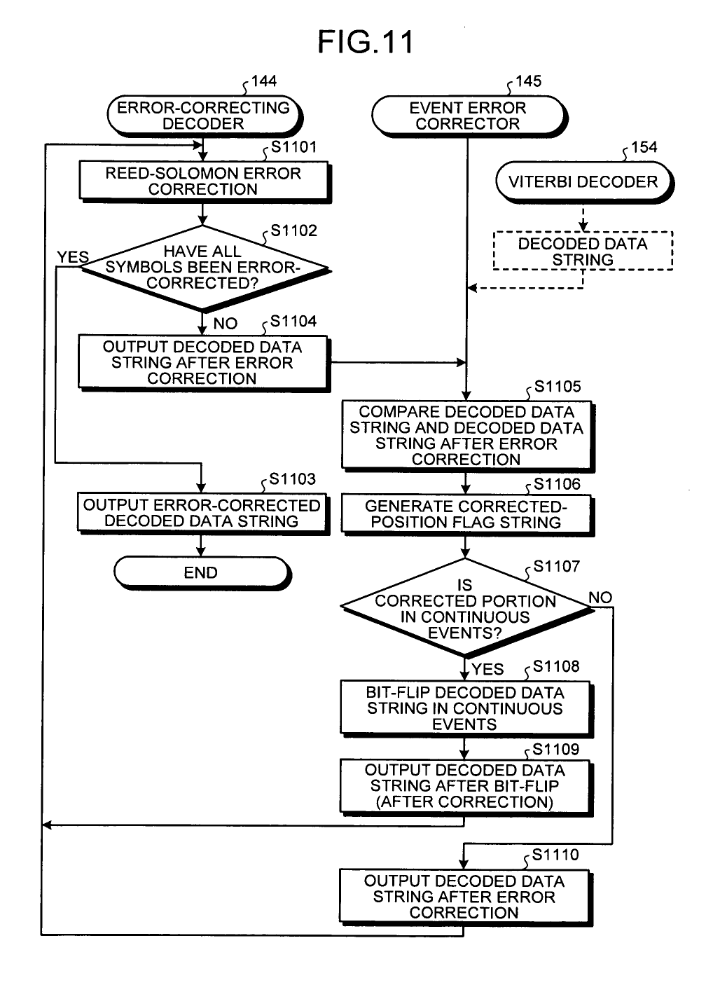

FIG. 11 is a flowchart of an operation flow of the magnetic disk device according to the first embodiment.

As depicted in the drawing, each Reed-Solomon error-correcting decoder 144b of the error-correcting decoder 144 performs error correction on the decoded data string input from the symbol interleaver unit 144a when a q-bit symbol is provided and a maximum number of symbol error corrections is taken as t (see Step S1101).

Each Reed-Solomon error-correcting decoder 144b inputs the decoded data string after error correction to the symbol de-interleaver unit 144c. The symbol de-interleaver unit 144c then checks to see whether all symbol errors in the error-corrected decoded data strings input from the Reed-Solomon error-correcting decoders 144b have been corrected (Step S1102).

As a result of the check, if all symbol errors in the error-corrected decoded data strings input from the Reed-Solomon error-correcting decoders 144b have been corrected (Yes at Step S1102), the symbol de-interleaver unit 144c outputs to the outside an error-corrected decoded data string (D′) obtained by deleting the ECC parity data string from the decoded data string after error correction for de-interleave (Step S1103).

On the other hand, if an symbol error is remained in any error-corrected decoded data string input from each of the Reed-Solomon error-correcting decoders 144b (No at Step S1102), the symbol de-interleaver unit 144c outputs to the event error corrector 145 a decoded data string after error correction (D′P′) obtained by de-interleaving the error-corrected decoded data strings (Step S1104).

The data comparator 145a of the event error corrector 145 then compares the decoded data string after error correction (D′P′) input from the symbol de-interleaver unit 144c and the decoded data string (DP) input from the Viterbi decoder 154 via the switching unit 140a (Step S1105).

The data comparator 145a then generates a corrected-position flag string indicative of an error-corrected portion in the decoded data string (DP), and outputs the generated corrected-position flag string to the bit-flip unit 145b together with the decoded data string after error correction (D′P′) (Step S1106).

Based on the decoded data string (DP) and the event information string input from the Viterbi decoder 154 via the switching unit 140a and the corrected-position flag input from the data comparator 145a, the bit-flip unit 145b checks to see whether the corrected portion in the decoded data string is in the event information string indicative of a merge section in the decoded data string (in continuous events) (step S1107).

As a result of the check, when it is confirmed based on the corrected-position flag input from the data comparator 145a that the corrected portion in the decoded data string also input from the data comparator 145a is in the event information string (in continuous events) indicative of a merge section in the decoded data string (Yes at Step S1107), the bit-flip unit 145b bit-flips (corrects) the data in the decoded data string for the merge section (continuous events) (Step S1108).

Then, the bit-flip unit 145b outputs the decoded data string after bit-flip (correction) again to the symbol interleaver unit 144a via the switching unit 140a (Step On the other hand, when it is not confirmed based on the corrected-position flag input from the data comparator 145a that the corrected portion in the decoded data string is in the event information string (in continuous events) (No at Step S1107), the bit-flip unit 145b outputs the decoded data string after error correction (D′P′) as it is to the symbol interleaver unit 144a (Step S1110).

[Effect of the First Embodiment]

As has been explained above, according to the first embodiment, by using the event information string obtained from the Viterbi decoder 154, symbols in the decoded data string are correlated with each other. Thus, an effect can be achieved such that an error event across symbols can be corrected without causing an incorrect sector even with the use of an interleave technique, thereby attaining a high correction capability.

Also, according to the first embodiment, by using the event information string obtained from the Viterbi decoder 154, symbols in the decoded data string are correlated with each other, and an error event across symbols can be corrected. Thus, an effect can be achieved such that a higher correction capability can be attained with fewer redundant data compared with a concatenated code technique or a product code technique.

Furthermore, according to the first embodiment, a process is iteratively performed between the error-correcting decoder 144 and the event error corrector 145 until all errors in the decoded data string have been corrected in the error-correcting decoder 144. Thus, an effect of attaining a higher correction capability can be achieved.

### Second Embodiment

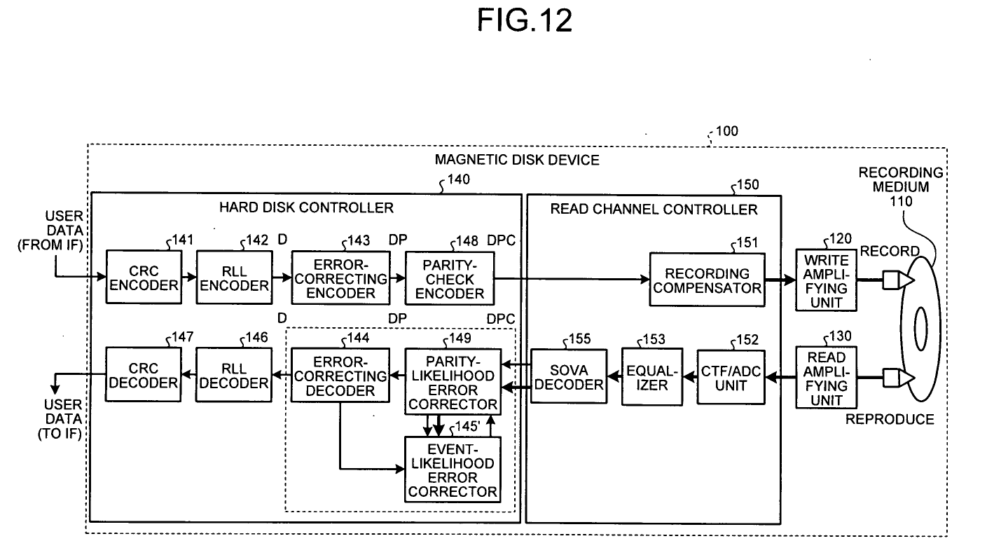

FIG. 12 is a block diagram of the configuration of a magnetic disk device according to a second embodiment. The magnetic disk device according to the second embodiment is different from that according to the first embodiment in the following points.

That is, the second embodiment is different from the first embodiment in that the hard disk controller 140 includes a parity-check encoder 148 and a parity-likelihood error corrector 149, and also includes an event-likelihood error corrector 145′ in place of the event error corrector 145.

Also, the second embodiment is different from the first embodiment in that the read channel controller 150 includes a Soft-Output Viterbi Algorithm (SOVA) decoder 155 in place of the Viterbi decoder 154.

The parity-check encoder 148 of the hard disk controller 140 is a device that generates a parity-check encoded data string (DPC) for output to the read channel controller 150.

Specifically, the parity-check encoder 148 adds p parity bits for every m bits to an encoded data string (DP) subjected to error-correcting encoding by the error-correcting encoder 143 (where m and p are integers equal to or greater than 1) to generate a parity-check encoded data string (DPC) for output to the read channel controller 150.

The SOVA decoder 155 of the read channel controller 150 is a device that outputs to the hard disk controller 140 a likelihood data string formed of a likelihood value indicative of a likelihood of each data forming the decoded data string, together with the decoded data string.

Here, each likelihood value of the likelihood data string has a property of indicating the same value in a merge section (events) in the decoded data string.

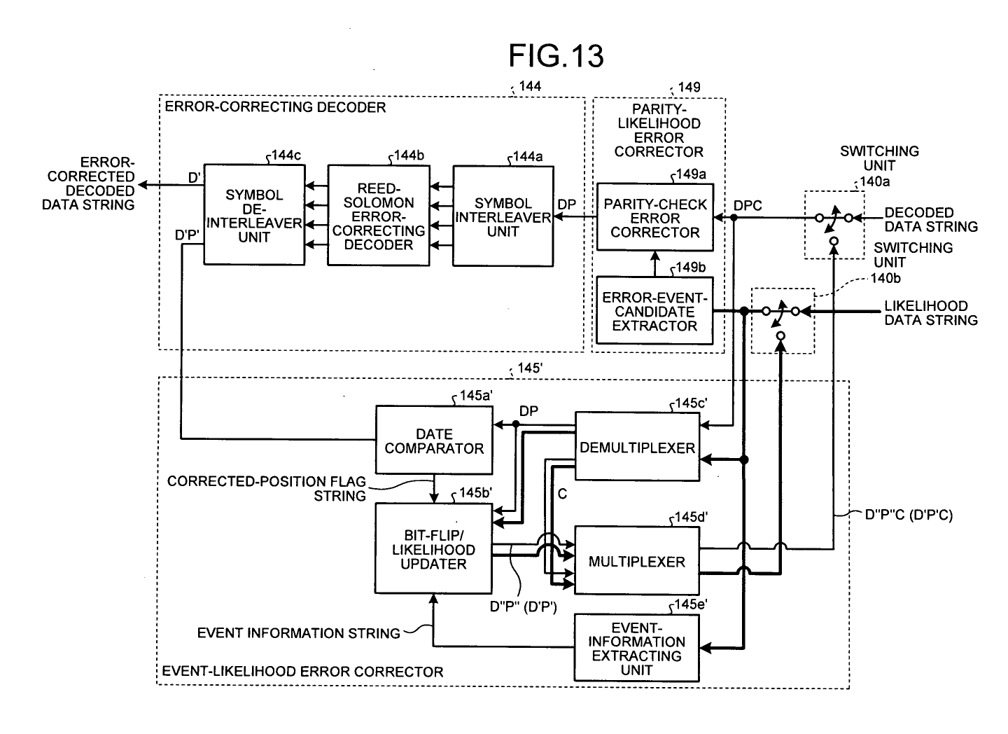

The parity-likelihood error corrector 149 of the hard disk controller 140 is a device that performs a parity check and error correction, and includes, as depicted in FIG. 13, a parity-check error corrector 149a and an error-event-candidate extractor 149b.

FIG. 13 is a block diagram of the configuration of the parity-likelihood error corrector, the error-correcting decoder, and the event-likelihood error corrector according to the second embodiment.

The error-event-candidate extractor 149b defines a unit with the same likelihood value as one event for every m+p bits of a likelihood data string input from the SOVA decoder 155, and extracts, for example, three events in order of increasing likelihood value from the minimum as error event candidates for output to the parity-check error corrector 149a.

The parity-check error corrector 149a performs a parity check and error correction for every m+p bits of a decoded data string (DPC) input from the SOVA decoder 155, and outputs the decoded data string (DP) after parity error correction for every m bits to the error correction decoder 144.

Specifically, the parity-check error corrector 149a uses the same polynomial as that for use in encoding at the parity-check encoder 148 to generate p parity bits for m bits of the encoded data string (DP), and then compares the generated parity bits and parity bits of the decoded data string (DPC) input from the SOVA decoder 155 for performing a parity check.

As a result of the comparison, when these parity bits match each other, the parity-check error corrector 149a determines as no error, and outputs to the error-correcting decoder 144 m bits of data obtained by deleting the parity bits from the decoded data string (DPC) as a parity error-corrected decoded data string (DP).

On the other hand, as a result of the comparison, when these parity bits do not match each other, the parity-check error corrector 149a determines that there is an error, and makes a correction by bit-flipping data in the decoded data string corresponding to an event having a minimum likelihood value from among error event candidates input from the error-event-candidate extractor 149b.

Next, the parity-check error corrector 149a regenerates p parity bits for m bits of the decoded data string after bit-flip to perform a parity check again in the manner as explained above.

As a result of the parity check, when these parity bits do not match each other, it is determined again that there is an error, and a similar parity check is performed for the next error event candidate input from the error-event-candidate extractor 149b.

Here, when all error event candidates input from the error-event-candidate extractor 149 do not pass the parity check, a parity check with a plurality of error event candidates being simultaneously corrected is tried.

The operation of the error-correcting decoder 144 is similar to that in the first embodiment explained above, and therefore is not explained herein.

The event-likelihood error corrector 145′ is a device that corrects the decoded data string after error correction (D′P′) and updates the likelihood data string, and includes, as depicted in FIG. 13, a data comparator 145a′, a bit-flip/likelihood updater 145b′, a demultiplexer 145c′, a multiplexer 145d′, and an event-information extracting unit 145e′.

The demultiplexer 145c′ outputs to the data comparator 145a′ a decoded data string (DP) with p parity-check bits separated from the decoded data string (DPC) input via the switching unit 140a for every m+p bits, and also outputs to the multiplexer 145d′ a parity data string (C) formed of parity-check bit portions.

Also, the demultiplexer 145c′ outputs to the bit-flip/likelihood updater 145b′ a likelihood data string with parity-check likelihood bits corresponding to the p parity-check bits separated from the likelihood data string input via a switching unit 140b for every m+p bits, and also outputs to the multiplexer 145′ a parity-data likelihood string formed of a likelihood portion of the parity-check bits.

The event-information extracting unit 145e′ switches “1” or “0” at a position where the likelihood value of the likelihood data string input via the switching unit 140b changes, generates an event-information data string in which “1”s or “0”s are continuously disposed at a position where the same likelihood values continue, and then outputs the event-information data string to the bit-flip/likelihood updater 145b′.

The data comparator 145′ compares the decoded data string after error correction (DTP′) input from the symbol de-interleaver unit 144c and the decoded data string (DP) input from the demultiplexer 145c′ to generate a corrected-position flag string as in the first embodiment, and then outputs the corrected-position flag string to the bit-flip/likelihood updater 145b′.

The bit-flip/likelihood updater 145b′ checks based on the decoded data string (DP) input from the demultiplexer 145c′, the event information string input from the event-information extracting unit 145e′, and the corrected-position flag input from the data comparator 145a to see whether the corrected portion in the decoded data string (DP) input from the demultiplexer 145c′ is in an event-information string (in continuous events) input from the event-information extracting unit 145e′.

Then, as with the first embodiment, when it is confirmed that the corrected portion in the decoded data string (DP) is in an event-information string (in continuous events), the bit-flip/likelihood updater 145b′ bit-flips the data in the decoded data string (DP) for the merge section (continuous events), and outputs the decoded data string after bit-flip (for example, D″P″) to the multiplexer 145d′.

Also, unlike the first embodiment, the bit-flip/likelihood updater 145b′ outputs to the multiplexer 145d′ an updated likelihood data string in which a likelihood value corresponding to a symbol error-corrected in the decoded data string after error correction (D′P′) and a likelihood value corresponding to the position bit-flipped in the decoded data string are updated to default maximum values for the likelihood data string (with the parity-check-code portion being separated) input from the demultiplexer 145c′.

On the other hand, when it is not confirmed that the corrected portion in the decoded data string is in an event-information string (in continuous events), the bit-flip/likelihood updater 145b′ outputs to the multiplexer 145d′ an updated likelihood data string with only the likelihood value corresponding to the symbol error-corrected in the decoded data string after error correction (D′P′), and the decoded data string after error correction (D′P′).

The multiplexer 145d′ outputs to the switching unit 140a a decoded data string obtained by inserting a parity data string (C) in the decoded data string (for example, D′P′ or D″P″) input from the bit-flip/likelihood updater 145b′.

The multiplexer 145d′ outputs to the switching unit 140b a likelihood data string obtained by multiplexing the updated likelihood data string input from the bit-flip/likelihood updater 145b′ into the parity-data likelihood string.

Then, from the switching unit 140a and the switching unit 140b to the parity-likelihood error corrector 149 and the event-likelihood error corrector 145′, the decoded data string and the likelihood data string are output. Then, among the parity-likelihood error corrector 149, the error-correcting decoder 144, and the event-likelihood error corrector 145′, the process explained above is again performed.

Here, the process iteratively performed among the parity-likelihood error corrector 149, the error-correcting decoder 144, and the event-likelihood error corrector 145′ is not meant to be restricted to a process iterated until an error-corrected decoded data string with all symbol errors corrected is output to the outside. An error-corrected decoded data string may be output to the outside after the process is iterated a predetermined number of times, irrespectively of the correction result.

[Process of the Magnetic Disk Device (Second Embodiment)]

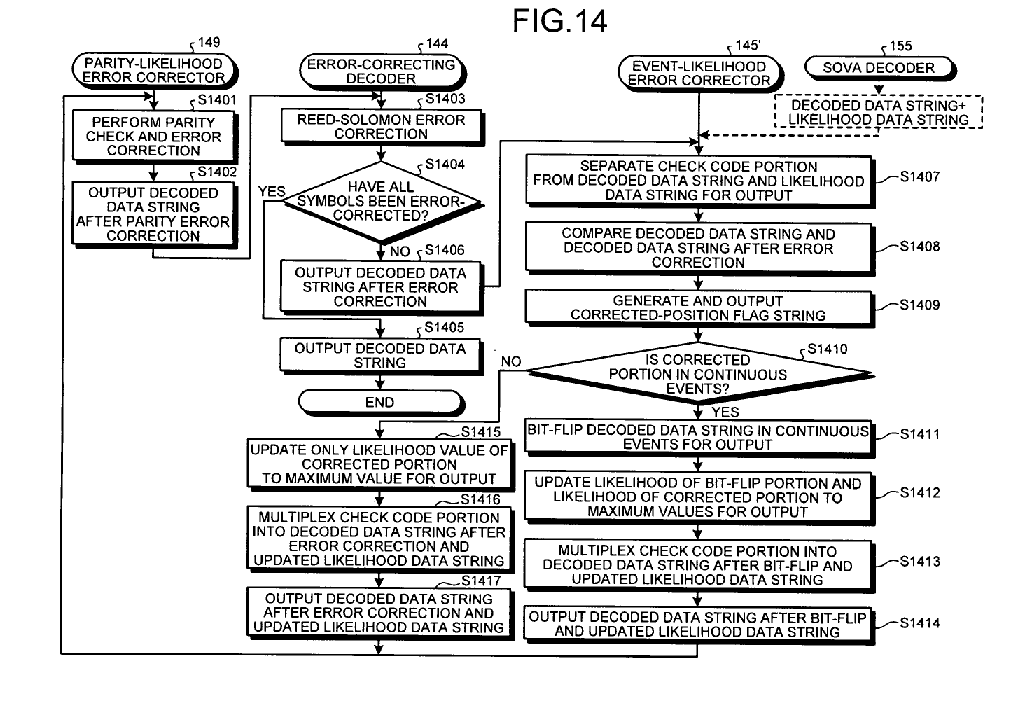

FIG. 14 is a flowchart of an operation flow of the magnetic disk device according to the second embodiment. Note that processes from steps S1403 to S1406 depicted in the drawing are similar to those in the first embodiment (see Steps S1101 to S1104 in FIG. 11), and therefore are not explained herein.

As depicted in the drawing, the parity-check error corrector 149a of the parity-likelihood error corrector 149 performs a parity check and error correction for every m+p bits of the decoded data string (DPC) input from the SOVA decoder 155 (Step S1401), and outputs the decoded data string (DP) after parity error correction for every m bits to the error-correcting decoder 144 (Step S1402).

The demultiplexer 145c′ of the event-likelihood error corrector 145′ separates a parity-check-code portion from the decoded data string and the likelihood data string input via the switching unit 140a, and outputs the parity-check-code portion to the bit-flip/likelihood updater 145b′ and also to the multiplexer 145d′ (Step S1407).

The data comparator 145a′ of the event-likelihood error corrector 145′ compares the decoded data string after error correction input from the symbol de-interleaver unit 144c of the error-correcting decoder 144 and the decoded data string input from the demultiplexer 145c′ (Step S1408) to generate a corrected-position flag string in a manner similar to that in the first embodiment, and then outputs the generated corrected-position flag string to the bit-flip/likelihood updater 145b′ (Step S1409).

The bit-flip/likelihood updater 145b′ checks based on the decoded data string input from the demultiplexer 145c′, the event information string input from the event-information extracting unit 145e′, and the corrected-position flag input from the data comparator 145a to see whether a corrected portion in the decoded data string input from the demultiplexer 145c′ is in the event information string (in continuous events) input from the event-information extracting unit 145e′ (Step S1410).

As with the first embodiment, when it is confirmed that a corrected portion in the decoded data string is in the event information string (in continuous events) (Yes at Step S1410), the bit-flip/likelihood updater 145b′ bit-flips the data in the decoded data string (DP) for the merge section (continuous events) for output to the multiplexer 145d′ (Step S1411).

Also, unlike the first embodiment, the bit-flip/likelihood updater 145b′ updates a likelihood value corresponding to a symbol error-corrected in the decoded data string after error correction and a likelihood value corresponding to the position bit-flipped in the decoded data string to default maximum values for the likelihood data string (with the parity-check-code portion being separated) input from the demultiplexer 145c′, and then outputs the results to the multiplexer 145d′ (Step S1412).

The multiplexer 145d′ multiplexes the parity-check-code portion into the decoded data string after bit-flip input from the bit-flip/likelihood updater 145b′ and the updated likelihood data string after updating the likelihood value (Step S1413).

The multiplexer 145d′ then outputs to the switching unit 140a the decoded data string obtained by multiplexing the parity-check-code portion, and also outputs to the switching unit 140b the likelihood data string obtained by multiplexing the parity-check-code portion (Step S1414).

Referring back to the explanation of Step S1410, when it is not confirmed that a corrected portion in the decoded data string is in the event information string (in continuous events) (No at Step S1410), the bit-flip/likelihood updater 145b′ updates only the likelihood value corresponding to the symbol error-corrected in the decoded data string after error correction, and then outputs the decoded data string after error correction and the updated likelihood data string to the multiplexer 145d, (Step S1415). The multiplexer 145d′ multiplexes the parity-check-code portion into the decoded data string after error correction input from the bit-flip/likelihood updater 145b′ and the updated likelihood data string after updating the likelihood value (Step S1416).

The multiplexer 145d′ then outputs to the switching unit 140a the decoded data string obtained by multiplexing the parity-check-code portion, and also outputs to the switching unit 140b the likelihood data string obtained by multiplexing the parity-check-code portion (Step S1417).

### [Effect of the Second Embodiment]

As has been explained above, according to the second embodiment, by using the likelihood data string obtained from the SOVA decoder 155, the event information extracted by the event-information extracting unit 145e′ is used, thereby correlating symbols in the decoded data string. Thus, an effect can be achieved such that an error event across symbols can be corrected without causing an incorrect sector even with the use of an interleave technique, thereby attaining a high correction capability.

Also, according to the second embodiment, the likelihood value is updated and defined to the maximum value in the event-likelihood error corrector 145′. Thus, an effect can be achieved such that, in a parity check and error correction by the parity-likelihood error corrector 149, error event candidates can be narrowed down, thereby more reliably performing error correction of the parity likelihood.

Furthermore, according to the second embodiment, a process is iteratively performed among the parity-likelihood error corrector 149, the error-correcting decoder 144 and the event-likelihood error corrector 145′ until all errors in the decoded data string have been corrected in the error-correcting decoder 144. Thus, an effect of attaining a higher correction capability can be achieved.

### Third Embodiment

### (1) Data Interleaving Method

In the embodiments, with the error-correcting encoder 143 (for example, see FIG. 4), for example, the information data string to be interleaved in units of symbols for encoding may be interleaved in units smaller than symbols.

Specifically, for an RLL-encoded data string formed of symbols each having q bits (q is an integer equal to or greater than 1), the error-correcting encoder 143 interleaves the information data string by r (r is an integer equal to or greater than 1), where r is equal to or greater than 1 and equal to or smaller than q and an integral multiple of r is q.

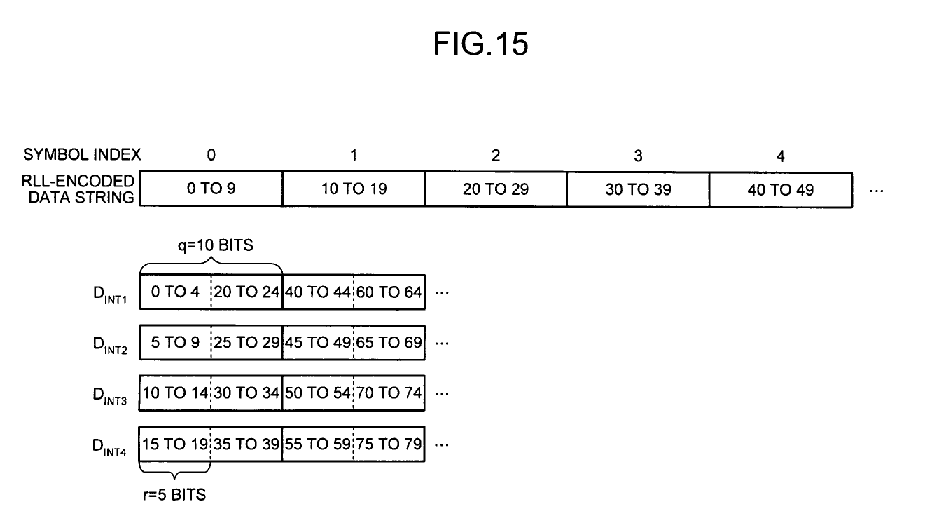

For example, as depicted in FIG. 15, when q=10 bits and r=5 bits, the error-correcting encoder 143 interleaves q=10 bits, which is one symbol of an information data string, by r=5 bits.

With this, for example, an effect can be achieved such that a probability that the event information in the Viterbi decoder 154 is across symbols can be increased, thereby attaining a higher correction capability.

### (2) Device Configuration and Others

Each component of the magnetic disk device 100 explained in the embodiments is conceptual in function, and is not necessarily physically configured as depicted. That is, the specific patterns of distribution and unification of the event error corrector 145 depicted in FIG. 9 are not meant to be restricted to those depicted in the drawings. All or part of the components can be functionally or physically distributed or unified in arbitrary units according to various loads and the state of use. For example, the data comparator 145a and the bit-flip unit 145b may be unified.

Furthermore, all or arbitrary part of the process functions performed in the magnetic disk device 100 explained in the embodiments (for example, see FIGS. 11 and 14) can be achieved by a Central Processing Unit (CPU) and a program analyzed and executed on that CPU, or can be achieved as hardware with a wired logic.

### (3) Decoding Method

With the magnetic disk device 100 explained in the embodiments, the following decoding method can be achieved.

That is, a decoding method is achieved including: a decoding step of causing the decoding unit to decode an information data string including an error-correction parity for each interleaved data string obtained by interleaving the information data string for each symbol to generate a decoded data string for output to an error-correcting decoding unit and an event error-correcting unit; an error-correcting decoding step (for example, see steps S1101 to S1104 in FIG. 11) of causing the error-correcting decoding unit to interleave the decoded data string output from the decoding unit for each symbol to perform error-correcting decoding, de-interleave the interleaved decoded data strings after error-correcting decoding for output to outside when all errors in the interleaved decoded data strings are corrected, and output to the event error-correcting unit a decoded data string after error correction obtained by de-interleaving the interleaved decoded data strings after error-correcting decoding when errors are remained in any of the interleaved decoded data strings; and an event error-correcting step (for example, see steps S1105 to S1108 in FIG. 11) of, when an error-corrected portion in the decoded data string obtained by comparing the decoded data string output from the decoding unit and the decoded data string after error correction output from the error-correcting decoding unit is in an event information string indicative of a merge section in the decoded data string, causing the event error-correcting unit to correct data in the decoded data string for the merge section.

Note that the decoding method explained above is not meant to be restricted to be applied to the magnetic disk device explained, but can also be similarly applied to, for example, a communication device for transmitting and receiving encrypted data.

For embodiments including those explained above, the following notes are further disclosed.

According to the embodiments of the present invention disclosed herein, an effect of achieving a high correction capability without causing an incorrect sector even with the use of an interleave technique can be attained.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A decoding device comprising:
a decoding unit that decodes an information data string including an error-correction parity for each interleaved data string obtained by interleaving the information data string for each symbol to generate a decoded data string;
an error-correcting decoding unit that interleaves the decoded data string input from the decoding unit for each symbol to perform error-correcting decoding, de-interleaves the interleaved decoded data strings after error-correcting decoding for output when all errors in the interleaved decoded data strings are corrected, and generates a decoded data string after error correction obtained by de-interleaving the interleaved decoded data strings after error-correcting decoding when errors are remained in any of the interleaved decoded data strings; and
an event error-correcting unit that receives the decoded data string from the decoding unit and the decoded data string after error correction from the error-correcting decoding unit, and when an error-corrected portion in the decoded data string obtained by comparing the decoded data string and the decoded data string after error correction is in an event information string indicative of a merge section in the decoded data string, corrects data in the decoded data string for the merge section.

2. The decoding device according to claim 1, wherein
the decoding unit generates a likelihood decoded data string obtained by likelihood-decoding the information data string and the event information string for output to the error-correcting decoding unit and the event error-correcting unit, and
when an error-corrected portion in the decoded data string obtained by comparing the likelihood decoded data string input from the decoding unit and the decoded data string after error correction input from the error-correcting decoding unit is in the event information string input from the decoding unit, the event error-correcting unit corrects data in the likelihood decoded data string for the merge section.

3. The decoding device according to claim 2, further comprising a data input unit that inputs an event error-corrected likelihood decoded data string corrected by the event error-correcting unit into the error-correcting decoding unit and the event error-correcting unit, wherein
the error-correcting decoding unit interleaves the event error-corrected likelihood decoded data string input from the data input unit for each symbol to perform error-correcting decoding, de-interleaves the interleaved event error-corrected likelihood decoded data strings for output to outside when all errors in the interleaved event error-corrected likelihood decoded data strings are corrected, and outputs to the event error-correcting unit a event error-corrected likelihood decoded data string after error correction obtained by de-interleaving the interleaved event error-corrected likelihood decoded data strings after error-correcting decoding when errors are remained in any of the interleaved event error-corrected likelihood decoded data strings, and
when an error-corrected portion in the event error-corrected likelihood decoded data string obtained by comparing the event error-corrected likelihood decoded data string input from the data input unit and the event error-corrected likelihood decoded data string after error correction input from the error-correcting decoding unit is in the event information string, the event error-correcting unit corrects data in the event error-corrected likelihood decoded data string for the merge section.

4. The decoding device according to claim 1, wherein
the decoding unit generates a decoded data string and a likelihood data string, the decoded data string being obtained by decoding the information data string further including a parity check code and the likelihood data string being formed of a likelihood value of each data corresponding to the decoded data string, and then outputs the decoded data string and the likelihood data string to the event error-correcting unit and a parity error-correcting unit,
the decoding device further comprises the parity error-correcting unit that performs a parity error correction on the decoded data string input from the decoding unit by using the likelihood data string input from the decoding unit, and then outputs the decoded data string after the parity error correction to the error-correcting decoding unit,
the error-correcting decoding unit interleaves the decoded data string after the parity error correction input from the parity error-correcting unit for each symbol to perform error-correcting decoding, de-interleaves the interleaved decoded data strings after error-correcting decoding for output to outside when all errors in the interleaved decoded data strings are corrected, and outputs to the event error-correcting unit a decoded data string after error correction obtained by de-interleaving the interleaved decoded data strings after error-correcting decoding when errors are remained in any of the interleaved decoded data strings, and
when an error-corrected portion in the decoded data string obtained by comparing the decoded data string input from the decoding unit and the decoded data string after error correction input from the error-correcting decoding unit is in an event information string generated from the likelihood data string input from the decoding unit, the event error-correcting unit corrects data in the decoded data string for the merge section, and updates a likelihood value in the likelihood data string input from the decoding unit to a maximum value for an error-corrected portion in the decoded data string and a data-corrected portion in the decoded data string.

5. The decoding device according to claim 4, further comprising a data likelihood input unit that inputs an event error-corrected decoded data string corrected by the event error-correcting unit and an updated likelihood data string obtained by updating a likelihood to the event error-correcting unit and the parity error-correcting unit, wherein
the parity error-correcting unit performs a parity error correction on the event error-corrected decoded data string input from the data likelihood input unit by using the updated likelihood data string input from the data likelihood input unit, and then outputs the event error-corrected decoded data string after the parity error correction to the error-correcting decoding unit,
the error-correcting decoding unit interleaves the event error-corrected decoded data string after the parity error correction input from the parity error-correcting unit for each symbol to perform error-correcting decoding, de-interleaves the interleaved event error-corrected decoded data strings after error-correcting decoding for output to outside when all errors in the interleaved event error-corrected decoded data strings are corrected, and outputs the event error-corrected decoded data strings after de-interleaving to the event error-correcting unit after error-correcting decoding when errors are remained in any of the interleaved event error-corrected decoded data strings, and
when an error-corrected portion in the event error-corrected decoded data string obtained by comparing the event error-corrected decoded data string input from the data likelihood input unit and the event error-corrected decoded data string after error correction input from the error-correcting decoding unit is in the event information string, the event error-correcting unit corrects data in the event error-corrected decoded data string for the merge section, and updates a likelihood value in the updated likelihood data string input from the data likelihood input unit to a maximum value for an error-corrected portion in the event error-corrected decoded data string and a data-corrected portion in the event error-corrected decoded data string.

6. The decoding device according to claim 1, wherein
the decoding unit decodes the information data string including an error correction parity for each interleaved data string obtained by interleaving the information data string for each symbol into strings and further interleaving each of the strings into units each smaller than the symbol.

7. A decoding method comprising:
a decoding unit to decode an information data string including an error-correction parity for each interleaved data string obtained by interleaving the information data string for each symbol to generate a decoded data string;
an error-correcting decoding unit to interleave the decoded data string output from the decoding unit for each symbol at the decoding to perform error-correcting decoding, de-interleave the interleaved decoded data strings after error-correcting decoding for output when all errors in the interleaved decoded data strings are corrected, and generate a decoded data string after error correction obtained by de-interleaving the interleaved decoded data strings after error-correcting decoding when errors are remained in any of the interleaved decoded data strings; and
an event error-correcting unit to receive the decoded data string from the decoding unit at the decoding and the decoded data string after error correction from the error-correcting decoding unit at the performing of error-correcting decoding, and when an error-corrected portion in the decoded data string obtained by comparing the decoded data string and the decoded data string after error correction is in an event information string indicative of a merge section in the decoded data string, and correct data in the decoded data string for the merge section.

8. The decoding method according to claim 7, wherein
at the decoding step, the decoding unit is caused to generate a likelihood decoded data string obtained by likelihood-decoding the information data string and the event information string for output to the error-correcting decoding unit and the event error-correcting unit, and
at the event error-correcting step, when an error-corrected portion in the decoded data string obtained by comparing the likelihood decoded data string output at the decoding step from the decoding unit and the decoded data string after error correction output from the error-correcting decoding unit is in the event information string output at the decoding step from the decoding unit, the event error-correcting unit is caused to correct data in the likelihood decoded data string for the merge section.

9. The decoding method according to claim 8, further comprising a data inputting step of causing a data input unit to input an event error-corrected likelihood decoded data string obtained through correction by the event error-correcting unit to the error-correcting decoding unit and the event error-correcting unit, wherein
at the error-correcting decoding step, the error-correcting decoding unit is caused to interleave the event error-corrected likelihood decoded data string input at the data input step from the data input unit for each symbol to perform error-correcting decoding, de-interleave the interleaved event error-corrected likelihood decoded data strings after error-correcting decoding for output to outside when all errors in the interleaved event error-corrected likelihood decoded data strings are corrected, and output to the event error-correcting unit an event error-corrected likelihood decoded data string after error correction obtained by de-interleaving the interleaved event error-corrected likelihood decoded data strings after error-correcting decoding when errors are remained in any of the interleaved event error-corrected likelihood decoded data strings, and
at the event error-correcting step, when an error-corrected portion in the event error-corrected likelihood decoded data string obtained by comparing the event error corrected likelihood decoded data string output at the data input step from the data input unit and the event error-corrected likelihood decoded data string after error correction output at the error-correcting decoding step from the error-correcting decoding unit is in the event information string, the event error-correcting unit is caused to correct data in the event error-corrected likelihood decoded data string for the merge section.

10. A recording and reproducing device comprising:
a decoding unit that decodes a reproducing data string reproduced from a recording medium by an error-correction data string in which an error-correction parity for each interleaved data string obtained by interleaving a information data string for each symbol is added to the information data string, to generate a decoded data string;
an error-correcting decoding unit that interleaves the decoded data string input from the decoding unit for each symbol to perform error-correcting decoding, de-interleaves the interleaved decoded data strings after error-correcting decoding for output when all errors in the interleaved decoded data strings are corrected, and generates a decoded data string after error correction obtained by de-interleaving the interleaved decoded data strings after error-correcting decoding when errors are remained in any of the interleaved decoded data strings; and
an event error-correcting unit that receives the decoded data string from the decoding unit and the decoded data string after error correction from the error-correcting decoding unit, and when an error-corrected portion in the decoded data string obtained by comparing the decoded data string and the decoded data string after error correction is in an event information string indicative of a merge section in the decoded data string, and corrects data in the decoded data string for the merge section.
